(19) United States
(12) Patent Application Publication
(10) Pub. No.: US 2026/0013241 A1
(43) Pub. Date: Jan. 8, 2026

(54) SEMICONDUCTOR STRUCTURE INCLUDING CMOS IMAGE SENSORS AND LOGIC TRANSISTORS AND METHOD FOR MANUFACTURING THE SAME

(71) Applicant: Taiwan Semiconductor Manufacturing Company, Ltd., Hsinchu (TW)

(72) Inventors: Yi-Hsuan FAN, Hsinchu (TW); Wen-Sheng WANG, Hsinchu (TW)

(73) Assignee: Taiwan Semiconductor Manufacturing Company, Ltd., Hsinchu (TW)

(21) Appl. No.: 18/765,564

(22) Filed: Jul. 8, 2024

(51) Int. Cl. H01L 27/146

(52) U.S. Cl. CPC H10F 39/802; H10F 39/014; H10F 39/18

(57) ABSTRACT

A method for manufacturing a semiconductor structure includes: forming an epitaxial layer having a pixel region and a logic region displaced from each other; forming a dielectric structure in the epitaxial layer such that the dielectric structure has a first depth in the logic region and a second depth in the pixel region, the second depth being smaller than the first depth; forming two diffusion isolation regions in the pixel region such that the two diffusion isolation regions each has a third depth that is greater than each of the first depth and the second depth, the pixel region having a pixel active area between the two diffusion isolation regions; forming a transfer gate on the pixel active area; forming a photosensitive region in the pixel active area for converting an incident light into charges; and forming a floating diffusion region in the pixel active area.

### BACKGROUND

An image sensor is a sensor capable of converting incoming phonons into electrons. The two major types of digital image sensor are complementary metal-oxide-semiconductor (CMOS) image sensor and charge-coupled device (CCD) image sensor. The CCD image sensor may have a configuration similar to that of metal-oxide-semiconductor capacitors, and the CMOS image sensor may have a configuration similar to that of metal-oxide-semiconductor field-effect transistor amplifiers. Sometimes, the CMOS image sensor and the CCD image sensor may be used in different products. For example, consumer electronic products with camera functions generally utilize the CMOS image sensor as image sensors thereof owing to relatively low power consumption, small size, fast data processing, and low cost of the CMOS image sensor, whereas high-end broadcast video cameras generally utilize the CCD image sensor as image sensors thereof.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 24 illustrate schematic views of intermediate stages of the method depicted in FIG. 1 in accordance with some embodiments.

FIG. 25 is a schematic top view of the semiconductor structure including a pixel region and a logic region in accordance with some other embodiments.

FIGS. 26 and 27 are enlarged fragmentary top views of area B shown in FIG. 25 illustrating a layout of the semiconductor structure in the pixel region in accordance with some different embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain regions(s)” may refer to a source or a drain, individually or collectively dependent upon the context.

Quantum efficiency (QE) and dark current are indexes for determining the performance of a complementary metal-oxide-semiconductor (CMOS) image sensor. Quantum efficiency represents the number of electrons (or holes) that can be generated for each phonon detected by an image sensor. The larger the value of quantum efficiency is, the better the performance of the CMOS image sensor is. Dark current represents the number of electrons (or holes) flowing in an image sensor even in the absence of light, and the smaller the value of dark current is, the better the performance of the CMOS image sensor is. Sometimes, defects in the image sensor may result in the occurrence of dark current. For a semiconductor structure including a CMOS image sensor and a logic circuit formed on the same wafer, a trench isolation, which is commonly used in the logic circuit for electrically isolating two adjacent ones of logic transistors, may also be used in the CMOS image sensor for electrically isolating two adjacent ones of pixel units. In a common practice, formation of the trench isolation includes forming a trench in a substrate by an etching process and filling the trench with a dielectric material by a deposition process. A plasma of reactive gases is often used in the etching process to facilitate chemical reactions during the etching process or to adjust the profile of the trench. It is noted that the substrate damage caused by the plasma increases as the depth of the trench increases, and such substrate damage may adversely affect the dark current performance of the CMOS image sensor. Therefore, the present disclosure is directed to methods for manufacturing a CMOS image sensor which can reduce, alleviate or eliminate the issue of substrate damage caused by the plasma, and embodiments of the CMOS image sensor respectively manufactured by the methods.

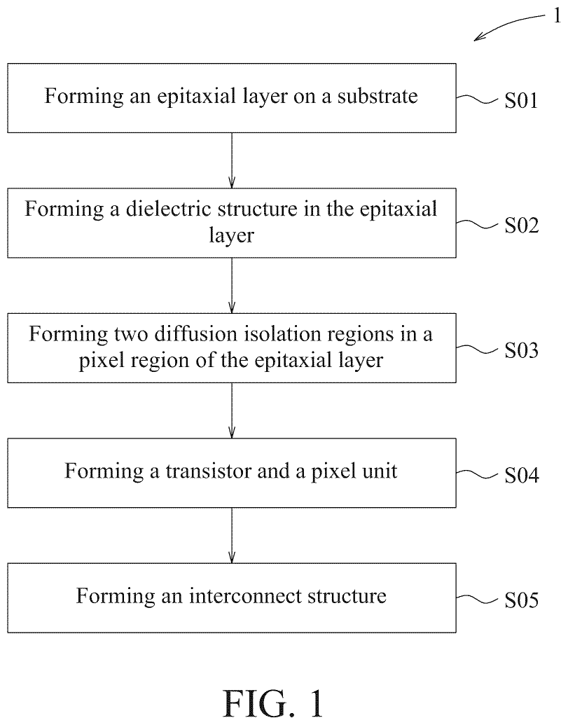

FIG. 1 is a flow diagram illustrating a method 1 for manufacturing a semiconductor structure (for example, but not limited to, a semiconductor structure 2 shown in FIG. 9) in accordance with some embodiments. As shown in FIG. 9, the semiconductor structure 2 includes a substrate 3, an epitaxial layer 41 formed on the substrate 3, and a dielectric structure 5 formed in the epitaxial layer 41. The dielectric structure 5 has a first depth (d1) in a logic region of the epitaxial layer 41 and has a second depth (d2) in a pixel region of the epitaxial layer 41. The pixel region and the logic region are displaced from each other. The second depth (d2) is smaller than the first depth (d1), and hence, a pixel unit 8 formed in the pixel region may have an improved pixel performance (e.g., a reduced dark current generated in the absence of an incident light) due to reduced substrate damage which is caused by, for example, but not limited to, an etching process (e.g., a plasma process). The semiconductor structure 2 further includes two diffusion isolation regions 6 in the pixel region, a transistor 7 and the pixel unit 8. The two diffusion isolation regions 6 each has a third depth (d3) that is greater than the first depth (d1) and the second depth (d2). Therefore, although the second depth (d2) in the pixel region is shallower than the first depth (d1) in the logic region, a photosensitive region 83 of the pixel unit 8 can be well isolated from the photosensitive region of an adjacent pixel unit.

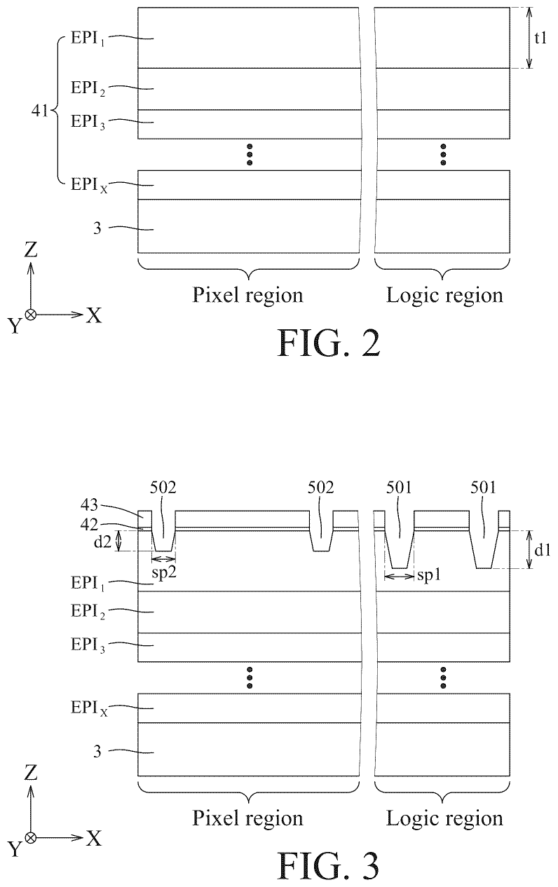

The method 1 may include steps S01 to S05. FIGS. 2 to 23 illustrate schematic views of intermediate stages of the method 1 in accordance with some embodiments.

Referring to FIG. 1 and the example illustrated in FIG. 2, the method 1 begins at step S01, where the epitaxial layer 41 is formed on the substrate 3.

In some embodiments, the substrate 3 includes elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 3 may be a bulk semiconductor substrate, for example, but not limited to, a bulk substrate of silicon, germanium, silicon germanium, or other suitable semiconductor materials (such as the examples described earlier in the same paragraph). In some embodiments, the semiconductor material in the substrate 3 may be doped with an n-type impurity to have an n-type conductivity, or may be doped with a p-type impurity to have a p-type conductivity. In some embodiments, the n-type impurity (or the p-type impurity) doped in the semiconductor material of the substrate 3 may be in a concentration ranging from about 1E17 atoms/cm³ to about 1E20 atoms/cm³. In some embodiments, the n-type impurity may include a group V element, for example, but not limited to, nitrogen (N), phosphorous (P), arsenic (As), antimony (Sb), other suitable materials, or combinations thereof. In some embodiments, the p-type impurity may include a group III element, for example, but not limited to, boron (B), aluminum (Al), gallium (Ga), indium (In), other suitable materials, or combinations thereof. In certain embodiments, the substrate 3 has a p-type conductivity and is referred to as a p-substrate. In some other embodiments not shown herein, the substrate 3 may be configured as a semiconductor-on-insulator substrate which includes an underlying handle layer, a device layer for forming the epitaxial layer 41 thereon, and a buried layer interposed between the underlying handle layer and the device layer. Each of the underlying handle layer and the device layer includes a semiconductor material such as the examples described earlier in the same paragraph. The buried layer may include an insulating material, for example, but not limited to, silicon oxide, silicon nitride, or silicon oxynitride. In such case, the device layer may be doped with the n-type impurity to have an n-type conductivity, or may be doped with the p-type impurity to have a p-type conductivity. Other materials or configurations suitable for the substrate 3 are within the contemplated scope of the present disclosure.

The epitaxial layer 41 includes a semiconductor material. Possible semiconductor materials suitable for forming the epitaxial layer 41 are similar to those for forming the substrate 3, and thus the details thereof are omitted for the sake of brevity. Other semiconductor materials suitable for the epitaxial layer 41 are within the contemplated scope of the present disclosure. The semiconductor material of the epitaxial layer 41 may be the same or different from the semiconductor material in the substrate 3. In some embodiments, the epitaxial layer 41 may be doped with an n-type impurity or a p-type impurity (such as the examples described in the previous paragraph) to have a conductivity type that is the same as the conductivity type of the substrate 3, but has a dopant concentration that is less than the dopant concentration of the substrate 3. In certain embodiments, the substrate 3 and the epitaxial layer 41 both have a p-type conductivity. In some embodiments, the epitaxial layer 41 is formed as a multi-layered structure, and includes multiple sub-layers EPI₁, EPI₂, EPI₃ . . . EPIₓ (where x is an integer greater than 3) stacked on the substrate 3 along a Z direction. The p-type impurity in the epitaxial layer 41 has a concentration gradient decreasing in a direction away from the substrate 3. That is, an upper one of the sub-layers has a dopant concentration that is less than a dopant concentration of a lower one of the sub-layers. In addition, an upper one of the sub-layers has a thickness that is greater than a lower one of the sub-layers.

For example, as shown in FIG. 2, the epitaxial layer 41 includes a first sub-layer EPI₁ and a second sub-layer EPI₂ immediately beneath the first sub-layer EPI₁. The sub-layer EP₁ is an uppermost one of the sub-layers on the substrate 3. The dopant concentration of the sub-layer EPI₁ is less than the dopant concentration of the sub-layer EPI₂. The thickness of the sub-layer EPI₁ is greater than the thickness of the sub-layer EPI₂. In some embodiments, the dopant concentration of the sub-layer EPI₁ ranges from about 1E13 atoms/cm³ to about 1E15 atoms/cm³. In some embodiments, the thickness (t1) of the sub-layer EPI₁ is greater than about 5 μm. As such, a p-n junction may be formed at a desired depth in the sub-layer EPI₁, thereby improving the quantum efficiency of the pixel unit 8 in response to an incident light (e.g., near-infrared light). In some embodiments, the epitaxial layer 41 may be formed on the substrate 3 by an epitaxial growth process. In some embodiments, the dopant concentration of each of the sub-layers EPI₁, EPI₂, EPI₃ . . . EPIₓ may be measured by secondary ion mass spectrometry (SIMS). In some embodiments, the thickness of each of the sub-layers EPI₁, EPI₂, EPI₃ . . . EPIₓ may be measured by spreading resistance profiling (SRP). In some embodiments, the sub-layers EPI₁ of the epitaxial layer 41 has the pixel region and the logic region.

Referring to FIG. 1 and the example illustrated in FIG. 5, the method 1 proceeds to step S02, where the dielectric structure 5 is formed in the sub-layer EPI₁, such that the dielectric structure 5 has the first depth (d1) in the logic region and has the second depth (d2) in the pixel region. FIG. 5 is a schematic sectional view similar to that shown in FIG. 2, but illustrating the structure after step S02. FIGS. 3, 4 and 5 respectively illustrate three possible intermediate states in step S02 in accordance with some embodiments.

In some embodiments, the second depth (d2) is greater than zero. In such case, the dielectric structure 5 includes two first trench isolations 51 formed in the logic region of the sub-layer EPI₁ and two second trench isolations 52 formed in the pixel region of the sub-layer EPI₁. Each of the first trench isolations 51 has the first depth (d1), and each of the second trench isolations 52 has the second depth (d2). In some embodiments, the second depth (d2) is not greater than a half of the first depth (d1). After formation of the dielectric structure 5, the logic region has a logic oxidation definition (OD) area (A1) between the two first trench isolations 51. The logic oxidation definition area (A1) may be also referred to as a logic active area.

In some embodiments, step S02 may include multiple sub-steps as described in the following.

Firstly, as shown in FIG. 3, the logic region of the sub-layer EPI₁ is patterned to form two first trenches 501 each having the first depth (d1), and the pixel region of the sub-layer EPI₁ is patterned to form two second trenches 502 each having the second depth (d2). A top opening of each of the first trenches 501 has a first length (sp1) in an X direction transverse to the Z direction, and a top opening of each of the second trenches 502 has a second length (sp2) in the X direction. In some embodiments, the second length (sp2) is smaller than the first length (sp1). In some embodiments, the second length (sp2) is smaller than the first length (sp1) by about 10% to about 20% of the first length (sp1).

In some embodiments, the first trenches 501 (as well as the second trenches 502) are formed by a photolithography process and an etching process. In some embodiments, prior to formation of the trenches 501, 502, a protection layer 42 and a polish stop layer 43 are sequentially formed on the epitaxial layer 41. In some embodiments, the protection layer 42 includes an oxide such as silicon oxide. The protection layer 42 is used to protect an upper surface of the epitaxial layer 41 from being contaminated or oxidized. In some embodiments, the polish stop layer 43 includes silicon nitride. Other suitable dielectric materials suitable for forming the protection layer 42 and the polish stop layer 43 are within the contemplated scope of the present disclosure. In some embodiments, the protection layer 42 has a thickness ranging from about 50 Å to about 300 Å. In some embodiments, the polish stop layer 43 has a thickness ranging from about 500 Å to about 2000 Å. In some embodiments, the protection layer 42 and the polish stop layer 43 may be formed by chemical vapor deposition (CVD), atomic layer deposition (ALD), or other suitable deposition techniques. To be specific, formation of the first trenches 501 may include (i) forming a patterned photoresist layer (not shown) partially on the polish stop layer 43 by a photolithography process to expose portions of the polish stop layer 43 which are in position corresponding to the first trenches 501 to be formed, (ii) performing an etching process to form the first trenches 501, each of which extends through the polish stop layer 43 and the protection layer 42 into the sub-layer EPI₁, and (iii) removing the patterned photoresist layer. In some embodiments, the first trenches 501 terminates at the sub-layer EPI₁ such that the first trenches 501 are spaced apart from the sub-layer EPI₂. The second trenches 502 may be formed in a manner similar to that for forming the first trenches 501, but process parameters (for example, but not limited to, thickness and position of the patterned photoresist layer, etching time, etc.) of the photolithography and etching processes are adjusted according to the configuration (e.g., position, spacing, depth, etc.) of the second trenches 502. In some embodiments, the first trenches 501 may be formed before or after formation of the second trenches 502.

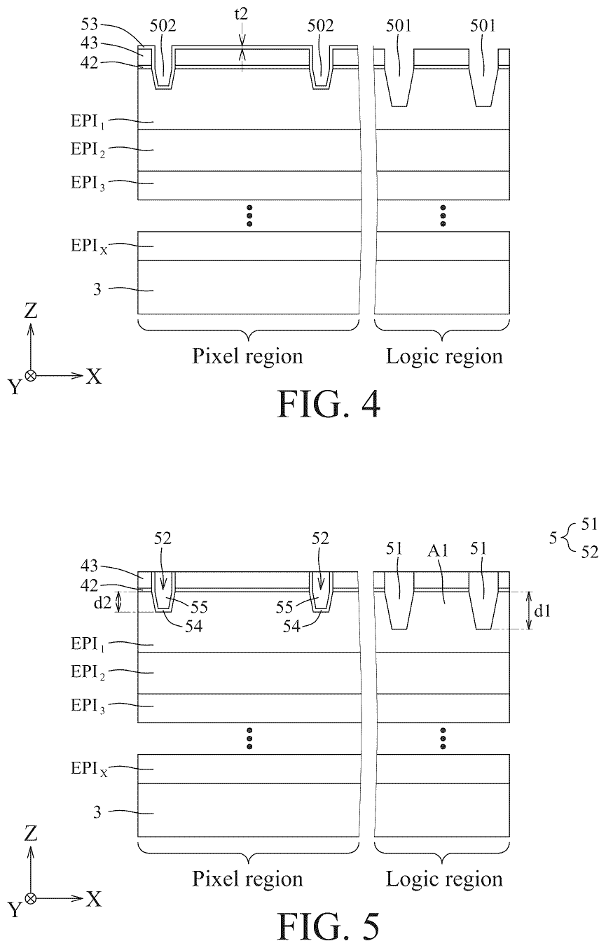

Afterwards, as shown in FIG. 4, a first dielectric layer 53 is formed on a portion of the polish stop layer 43 located in the pixel region to cover inner surfaces of the second trenches 502. In some embodiments, the first dielectric layer 53 is made of a first dielectric material which includes metal oxide including hafnium, aluminum, tantalum, other suitable metal materials, or combinations thereof. For example, the first dielectric material includes hafnium oxide, aluminum oxide, or tantalum oxide. In some embodiments, the first dielectric layer 53 has a thickness (t2) ranging from about 10 Å to about 120 Å. In some embodiments, formation of the first dielectric layer 53 may include forming a metal oxide layer (not shown) conformally on the structure in the pixel and logic regions shown in FIG. 3 by plasma-free CVD, plasma-free ALD or other suitable deposition techniques without plasma assistance, followed by a photolithography process and an etching process to remove a first portion of the metal oxide layer in the logic region, while leaving a second portion of the metal oxide layer in the pixel region. It is noted that, with provision of the first dielectric layer 53, holes (or electron holes, which are positively charged) in the diffusion isolation regions 6 may tend to diffuse toward the inner surfaces of the second trenches 502, so that dangling bonds (or free electrons) on the inner surfaces may be eliminated (or neutralized) by the holes. When the thickness of the first dielectric layer 53 is less than about 10 Å, the number of the holes may be insufficient to repair the dangling bonds on the inner surfaces of the trenches 502. When the thickness of the first dielectric layer 53 is greater than about 120 Å, filling the trenches 502 with a second dielectric material in the next sub-step as shown in FIG. 5, may be more difficult to be performed. In some embodiments, the first dielectric layer 53 is a non-doped layer (i.e., an intrinsic dielectric layer).

Next, as shown in FIG. 5, the first and second trenches 501, 502 are filled with the second dielectric material which is different from the first dielectric material, thereby obtaining the trench isolations 51, 52 respectively formed in the trenches 501, 502. To be specific, a second dielectric layer (not shown) which includes the second dielectric material is formed on the structure shown in FIG. 4 to fill the first and second trenches 501, 502 by furnace oxidation, CVD, ALD or other suitable deposition techniques, and then a planarization process (for example, but not limited to, a chemical mechanical polishing) is performed until the polish stop layer 43 is exposed. Accordingly, the first dielectric layer 53 is formed into dielectric films 54 each having a thickness ranging from about 10 Å to about 120 Å, and the second dielectric layer is formed into the first trench isolations 51 in the logic region and dielectric portions 55 in the pixel region. The dielectric portions 55 are respectively formed on the dielectric films 54. Each of the second trench isolations 52 includes one of the dielectric portions 55 and a corresponding one of the dielectric films 54. Each of the first trench isolations 51 has the first length (sp1, see FIG. 3) in the X direction, and each of the second trench isolations 52 has the second length (sp2, see FIG. 3) in the X direction. In some embodiments, the second dielectric material includes silicon oxide, silicon nitride, silicon oxynitride, carbon-doped silicon oxide, silicon oxycarbon nitride, other suitable dielectric materials or combinations thereof.

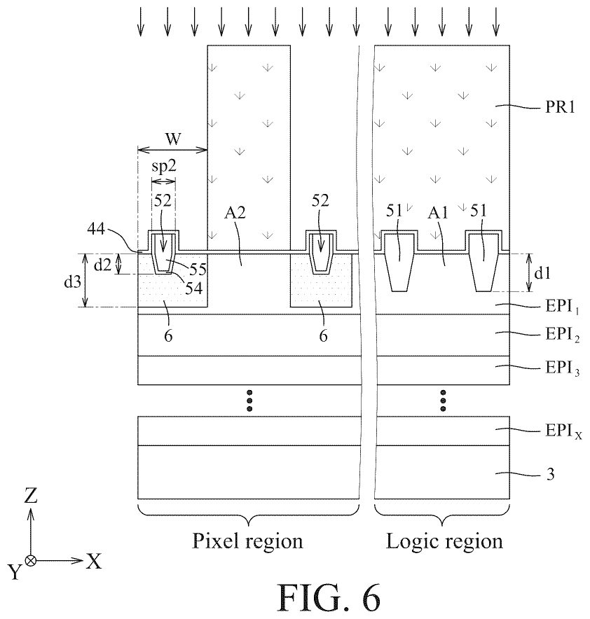

Referring to FIG. 1 and the example illustrated in FIG. 6, the method 1 proceeds to step S03, where the diffusion isolation regions 6 are formed in the pixel region of the sub-layer EPI₁. FIG. 6 is a schematic sectional view similar to that shown in FIG. 5, but illustrating the structure after step S03.

The diffusion isolation regions 6 are formed around the second trench isolations 52, respectively. Hence, as shown in FIG. 6, the second trench isolations 52 are respectively located within the diffusion isolation regions 6. The pixel region has a pixel active area (A2) between the diffusion isolation regions 6. In some embodiments, an upper surface of the diffusion isolation regions 6 have a width (W) in the X direction that is greater the second length (sp2). The diffusion isolation regions 6 are doped with an n-type impurity or a p-type impurity (such as the examples described in the previous paragraph with reference to FIG. 2) to have a conductivity type that is the same as the conductivity type of the sub-layer EPI₁, but the diffusion isolation regions 6 each has a dopant concentration that is greater than the dopant concentration of the sub-layer EPI₁ and that is less than the dopant concentration of the sub-layer EPI₂. In some embodiments, both the epitaxial layer 41 and the diffusion isolation regions 6 have a p-type conductivity. In some embodiments, the diffusion isolation regions 6 are spaced apart from the sub-layer EPI₂. In some embodiments, the doping concentration of each of the diffusion isolation regions 6 ranges about 1E13 atoms/cm³ to about 1E15 atoms/cm³.

In some embodiments, the diffusion isolation regions 6 are formed by a first ion implantation process, as shown in FIG. 6. During the first ion implantation process, the logic region and a first portion of the pixel region are protected by a patterned photoresist layer (PR1) to expose a second portion of the pixel region for forming the diffusion isolation regions 6. After the first ion implantation process and before proceeding to the next step, the patterned photoresist layer (PR1) will be removed.

In some embodiments, prior to the first ion implantation process, the polish stop layer 43 and the protection layer 42 (see FIG. 5) are removed by an etching process such as dry etching and/or wet etching, and then a sacrificial layer 44 is formed to cover the sub-layer EPI₁ and the trench isolations 51, 52. In some embodiments, the sacrificial layer 44 includes silicon oxide or other suitable dielectric materials. In some embodiments, the sacrificial layer 44 is formed by furnace oxidation, CVD, ALD, or other suitable deposition techniques.

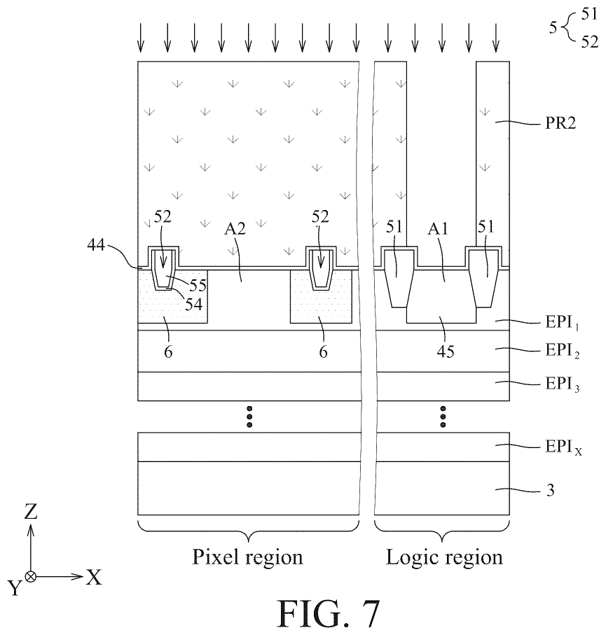

In some embodiments, before or after formation of the diffusion isolation regions 6, a logic well 45 is further formed in the logic active area (A1) of the sub-layer EPI₁, as shown in FIG. 7. When the sub-layer EPI₁ has a p-type conductivity and the transistor 7 to be formed on the sub-layer EPI₁ is a p-type transistor, the logic well 45 having an n-type conductivity is formed in the logic active area (A1) of the sub-layer EPI₁ for well isolation of the p-type transistor. On the contrary, when the sub-layer EPI₁ has an n-type conductivity and the transistor 7 to be formed on the sub-layer EPI₁ is an n-type transistor, the logic well 45 having a p-type conductivity is formed in the logic active area (A1) of the sub-layer EPI₁ for well isolation of the n-type transistor. In some embodiments, the logic well 45 is formed by a second ion implantation process. During the second ion implantation process, the pixel region and a first portion of the logic region are protected by a patterned photoresist layer (PR2) to expose a second portion of the logic region for forming the logic well 45. After the second ion implantation process and before proceeding to the next step, the patterned photoresist layer (PR2) will be removed. The logic well 45 may be formed before or after formation of the diffusion isolation regions 6.

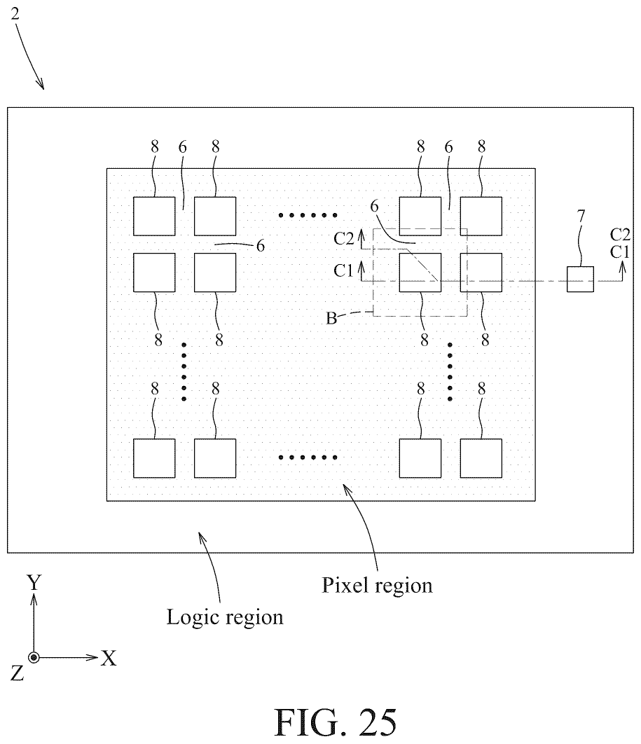

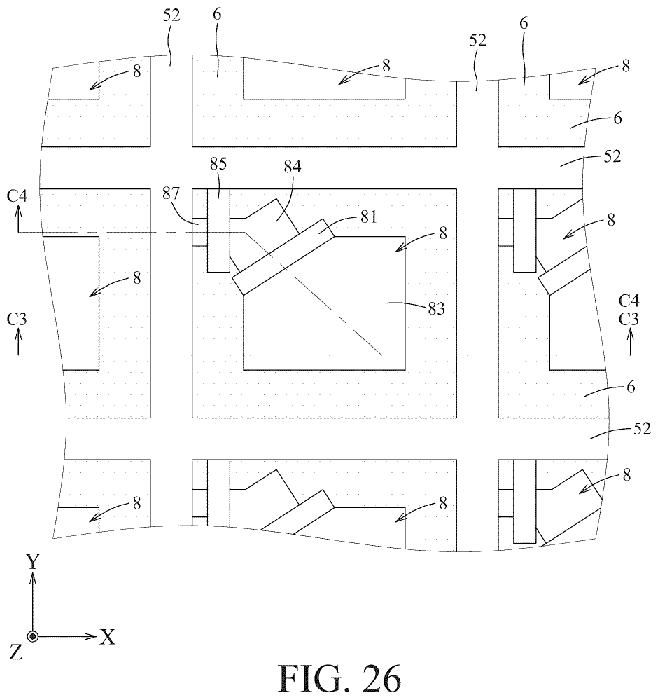

Referring to FIG. 1 and the example illustrated in FIG. 9, the method 1 proceeds to step S04, where the transistor 7 and the pixel unit 8 are formed, thereby obtaining the semiconductor structure 2. FIG. 9 is a schematic sectional view similar to that shown in FIG. 7, but illustrating the structure after step S04. FIG. 25 is a schematic top view illustrating the semiconductor structure 2 in accordance with some embodiments, and FIG. 26 is an enlarged fragmentary view of area B shown in FIG. 25 illustrating a layout example of the pixel unit 8 in accordance with some embodiments. In some embodiments, FIG. 7 illustrates the sectional view of the intermediate structure obtained after step S03 which is taken along line C1-C1 of FIG. 25, whereas FIG. 9 illustrates the sectional view of the intermediate structure obtained after step S04 which is taken along line C2-C2 of FIG. 25. The pixel region shown in FIG. 7 is taken along line C3-C3 of FIG. 26, while the pixel region shown in FIG. 9 is taken along line C4-C4 of FIG. 26.

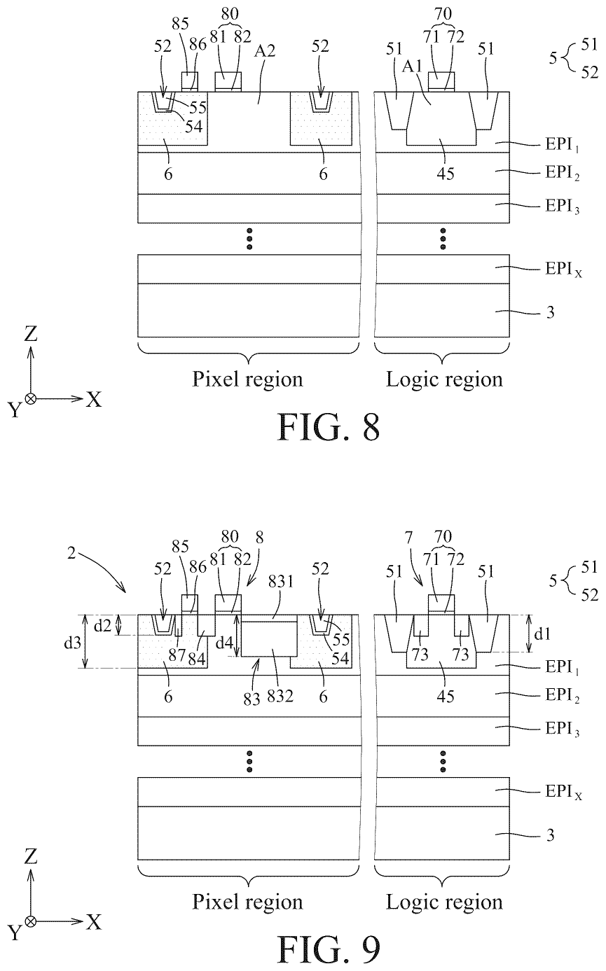

FIGS. 8 and 9 respectively illustrate two possible intermediate states in step S04 in accordance with some embodiments. In some embodiments, prior to formation of the transistor 7 and the pixel unit 8, the sacrificial layer 44 (see FIG. 7) is removed by an etching process such as dry etching and/or wet etching.

The transistor 7 includes a logic gate 70 and two source/drain regions 73. The logic gate 70 is formed on the logic active area (A1, see FIG. 8). The two source/drain regions 73 are formed in the logic active area (A1), and are respectively located at two opposite sides of the logic gate 70. In some embodiments, the logic gate 70 includes a logic gate electrode 71 and a logic gate dielectric 72 disposed to separate the logic gate electrode 71 from the logic active area (A1). The logic gate electrode includes polycrystalline silicon or other suitable materials. The logic gate dielectric 72 includes silicon oxide or other suitable dielectric materials. In some embodiments, when the transistor 7 is an n-FET, the two source/drain regions 73 are doped with an n-type impurity (such as the examples described in the previous paragraph with reference to FIG. 2). In some other embodiments, when the transistor 7 is a p-FET, the two source/drain regions 73 are doped with a p-type impurity (such as the examples described in the previous paragraph with reference to FIG. 2). When the conductivity type of the source/drain regions 73 are opposite to the conductivity type of the sub-layer EPI₁, the sub-layer EPI₁ may serve as a well for isolation. When the conductivity type of the source/drain regions 73 are the same as the conductivity type of the sub-layer EPI₁, the logic well 45 will be formed for well isolation. In such case, the source/drain regions 73 are formed in the logic well 45, and thus a leakage current may be less likely to flow from one of the source/drain portions 73 toward the substrate 3.

The pixel unit 8 includes a transfer gate 80, a photosensitive region 83, and a floating diffusion region 84.

The transfer gate 80 is formed on the pixel active area (A2, see FIG. 8), and includes a transfer gate electrode 81 and a transfer gate dielectric 82 disposed to separate the transfer gate electrode 81 from the pixel active area (A2). In some embodiments, the transfer gate electrode 81 includes polycrystalline silicon or other suitable materials. In some embodiments, the transfer gate dielectric 82 includes silicon oxide or other suitable dielectric materials. The photosensitive region 83 and the floating diffusion region 84 are formed in the pixel active area (A2), and are respectively located at two opposite sides of the transfer gate electrode 81. The photosensitive region 83 is used for converting an incident light into charges, and is formed in the pixel active area (A2). In some embodiments, the photosensitive region 83 occupies the majority of the pixel active area (A2). The photosensitive region 83 has a fourth depth (d4) that is less than the third depth (d3). The photosensitive region 83 includes a p-n junction which is formed by an upper doped zone 831 and a lower doped zone 832 which is in contact with and located beneath the upper doped zone 831. The upper doped zone 831 has a conductivity type that is the same as the conductivity of the sub-layer EPI₁, and has a dopant concentration that is greater than the dopant concentration of the sub-layer EPI₁. The lower doped zone 832 has a conductivity type that is opposite to the conductivity of the sub-layer EPI₁, and has a dopant concentration that is greater than the dopant concentration of each of the diffusion isolation regions 6. In some embodiments, the photosensitive region 83 in the pixel active area (A2) may extend into a first one (e.g., a right one shown in FIG. 9) of the diffusion isolation regions 6. The floating diffusion region 84 has a conductivity type that is the same as the lower doped zone 832, and has a dopant concentration that is greater than the dopant concentration of each of the diffusion isolation regions 6. In some embodiments, the floating diffusion region 84 in the pixel active area (A2) may extend into a second one (e.g., a left one shown in FIG. 9) of the diffusion isolation regions 6.

In certain embodiments, the sub-layer EPI₁ and the upper doped zone 831 have a p-type conductivity, while the lower doped zone 832 and the floating diffusion region 84 have an n-type conductivity. In such case, upon irradiation of an incident light, charges (e.g., electrons) are photoelectrically-converted in the p-n junction in response to an incident light, and then are accumulated in the lower doped zone 832. A leakage of the charges may be suppressed due to good electrical isolation formed by the sub-layer EPI₁ and the diffusion isolation regions 6. In response to a voltage applied to the transfer gate electrode 81, the charges stored in the lower doped zone 832 are transferred to the floating diffusion regions 84 through a channel which is located between the lower doped zone 832 and the floating diffusion regions 84 and which is located beneath the transfer gate 80.

In some embodiments, the pixel unit 8 further includes a reset gate electrode 85, a reset gate dielectric 86 and a reset diffusion region 87. The reset gate electrode 85 is formed on the second one of the diffusion isolation regions 6 and spaced apart from the transfer gate electrode 81. In some embodiments, the reset gate electrode 85 includes polycrystalline silicon or other suitable materials. The reset gate dielectric 86 is disposed to separate the reset gate electrode 85 from the second one of the diffusion isolation regions 6. In some embodiments, the reset gate dielectric 86 includes silicon oxide or other suitable dielectric materials. The reset diffusion region 87 are formed in the second one of the diffusion isolation regions 6 such that the floating diffusion region 84 and the reset diffusion region 87 are respectively located at two opposite sides of the reset gate electrode 85. The reset diffusion region 87 has a conductivity type that is the same as the conductivity type of the floating diffusion region 84, and has a dopant concentration that is greater than each of the diffusion isolation regions 6. In other words, the conductivity type of each of the reset diffusion region 87 and the floating diffusion region 84 is opposite to the conductivity type of the diffusion isolation regions 6. In response to a voltage applied to the reset gate electrode 85, the floating diffusion region 84 may be charged or discharged to reset the electric potential of the floating diffusion region 84.

In some embodiments, step S04 may include multiple sub-steps as described in the following.

Firstly, as shown in FIG. 8, the logic gate electrode 71, the logic gate dielectric 72, the transfer gate electrode 81, the transfer gate dielectric 82, the reset gate electrode 85, and the reset gate dielectric 86 are formed. In some embodiments, formation of the elements 71, 72, 81, 82, 85, 86 may include (i) forming a gate dielectric layer (not shown) for forming the gate dielectrics 72, 82, 86 on the sub-layer EPI₁ by furnace oxidation, chemical vapor deposition (CVD), or other suitable deposition techniques, (ii) forming a gate electrode layer (not shown) for forming the gate electrodes 71, 81, 85 on the gate dielectric layer, and (iii) patterning the gate electrode layer and the gate dielectric layer by a patterning process including photolithography and etching processes. In some other embodiments, the gate dielectrics 72, 82, 86 may have different thicknesses. In such case, prior to formation of the gate electrode layer, multiple dielectric layers (not shown) which are respectively for the gate dielectrics 72, 82, 86 and which are displaced from each other and have different thicknesses are formed on the sub-layer EPI₁. The dielectric layers may be formed by multiple deposition processes and multiple patterning processes (each including a photolithography process and an etching process). In some embodiments, portions of the dielectric structure 5 protruding from an upper surface of the sub-layer EPI₁ (see FIG. 7) are removed by the patterning processes during formation of the elements 71, 72, 81, 82, 85, 86.

Afterwards, as shown in FIG. 9, the source/drain regions 73, the photosensitive region 83, the floating diffusion region 84, and the reset diffusion region 87 are formed. Each of the source/drain regions 73, the photosensitive region 83, the floating diffusion region 84, and the reset diffusion region 87 may be formed by implantation process(es), while a patterned photoresist layer (not shown) covers the structure shown in FIG. 8 to expose a desirable region to be implanted.

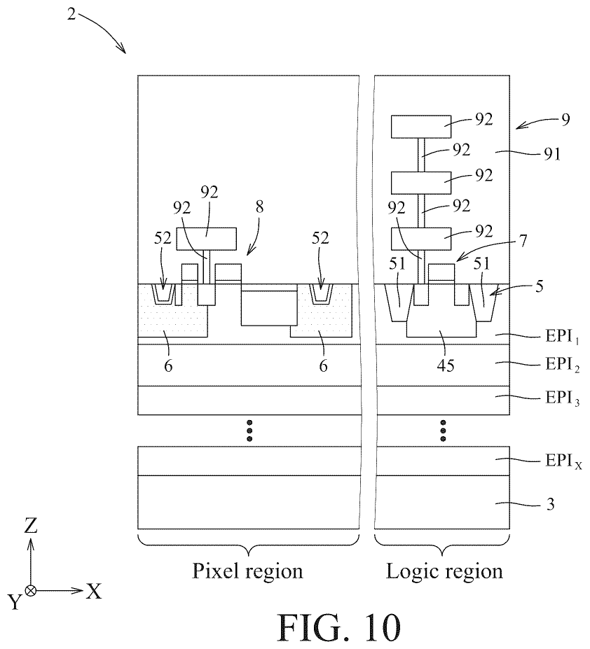

Referring to FIG. 1 and the example illustrated in FIG. 10, the method 1 proceeds to step S05, where the semiconductor structure 2 is further formed with an interconnect structure 9 disposed on the transistor 7 and the pixel unit 8 so as to permit the transistor 7 and the pixel unit 8 to be controlled by an external circuit. FIG. 10 is a schematic sectional view similar to that shown in FIG. 9, but illustrating the structure after step S05.

In some embodiments, the interconnect structure 9 may include an inter-layer dielectric (ILD) portion 91 (or an inter-metal dielectric (IMD) portion) in which a plurality of electrically conductive elements 92 (for example, metal contacts, metal lines and/or metal vias) are formed so as to permit each of the transistor 7 and the pixel unit 8 to be electrically connected to the external circuit through the electrically conductive elements 92. The interconnect structure 9 may be formed by a dual damascene process, a single damascene process, or other suitable back-end-of-line (BEOL) techniques.

In some embodiments, some steps in the method 1 may be modified, replaced, or eliminated without departure from the spirit and scope of the present disclosure.

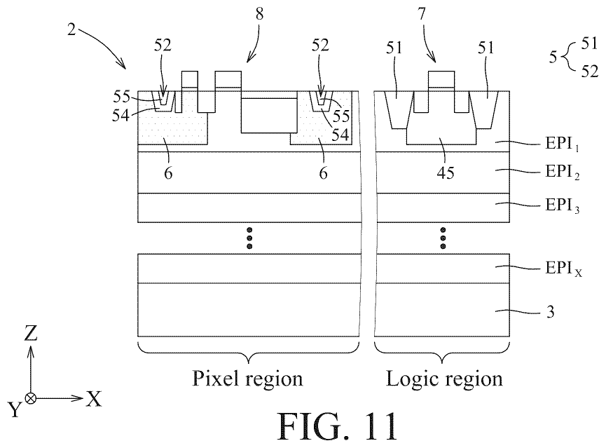

For example, the second trench isolations 52 may have different configurations. FIG. 11 is a schematic view similar to that shown in FIG. 9, but each of the dielectric films 54 shown in FIG. 11 has an increased thickness in comparison with the thickness of each of the electric films 54 shown in FIG. 9. The thickness of the dielectric films 54 shown in FIG. 11 is also in a range of about 10 Å to about 120 Å. Since the thickness of each of the dielectric films 54 is relatively large, the pixel unit 8 in the semiconductor structure 2 shown in FIG. 11 has an improved pixel performance (e.g., a reduced dark current) in comparison with the pixel unit 8 in the semiconductor structure shown in FIG. 9.

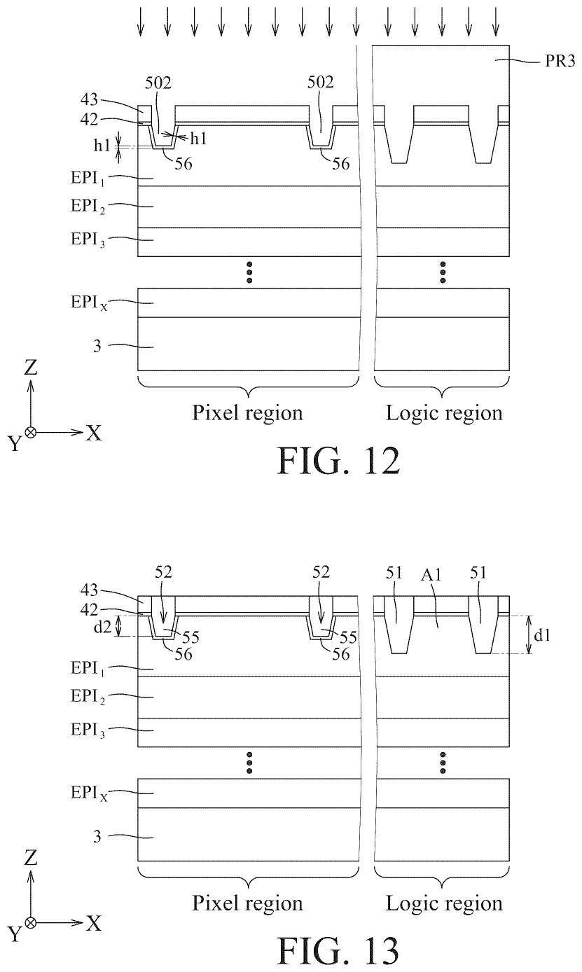

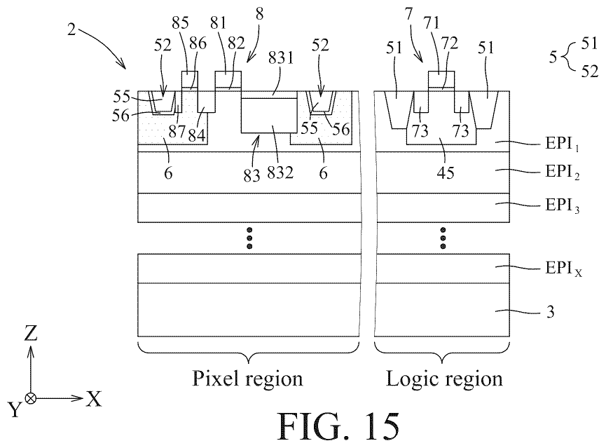

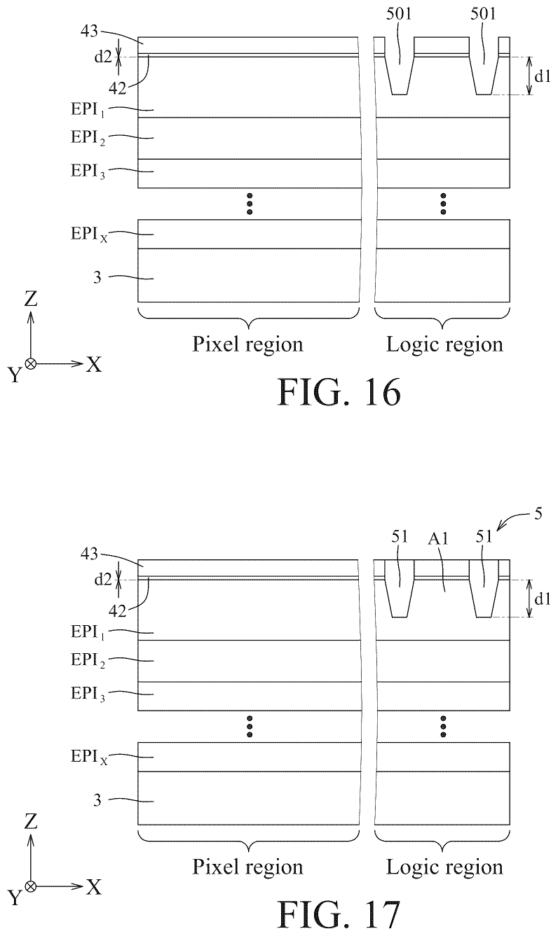

In some other embodiments, the second trench isolations 52 shown in FIG. 15 may be formed by different processes. FIGS. 12 and 13 respectively illustrate two possible intermediate states in step S02 for forming the second trench isolations 52 shown in FIG. 15 in accordance with some other embodiments. Step S02 may be performed in a manner similar to that as described above with reference to FIGS. 3 to 5, but formation of the first dielectric layer 53 (see FIG. 4) is omitted, and a treatment (see FIG. 12) is performed on the inner surfaces of the second trenches 502 using a p-type impurity (such as the examples described in the previous paragraph with reference to FIG. 2) to from peripheral doped regions 56 in the sub-layer EPI₁. In such case, after the filing of the first and second trenches 501, 502, the trench isolations 51, 52 shown in FIG. 12 are formed, and each has a structure similar that shown in FIG. 5, but the dielectric films 54 shown in FIG. 5 are absent, and the dielectric portions 55 of the second trench isolations 52 are in contact with the inner surfaces of the second trenches 502, respectively. It is noted that, in the case that the first dielectric layer 53 is formed to cover the inner surfaces of the second trenches 502 so as to repair the dangling bonds on the inner surfaces of the trenches 502, as shown in FIG. 4, the treatment for forming the peripheral doped regions 56 (see FIG. 12) is omitted before the first dielectric layer 53 is formed.

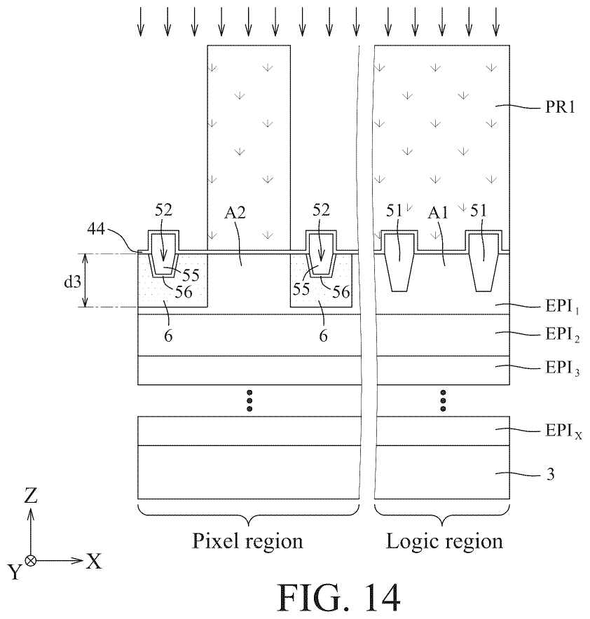

In some embodiments, as shown in FIG. 12, the treatment is performed by subjecting the pixel region to an implantation process, while the logic region is protected by a patterned photoresist layer (PR3). During the treatment, a p-type impurity (such as the examples described in the previous paragraph with reference to FIG. 2) is implanted the epitaxial layer (41, EPI₁) with a depth (h1) from the inner surfaces of the two second trenches 502. In some embodiments, the depth (h1) is not greater than about 1000 Å. In some embodiments, the p-type impurity in each of the peripheral doped regions 53 may be in a doping concentration ranging about 1E12 atoms/cm³ to about 1E14 atoms/cm³. After the treatment and before proceeding to the next sub-step (i.e., the filling of the trenches 501, 502), the patterned photoresist layer (PR3) will be removed. With provision of the treatment, dangling bonds (or free electrons) on the inner surfaces of the second trenches 502 may be eliminated by the p-type impurity, thereby improving a pixel performance (e.g., dark current) of the pixel unit 8. It is noted that no matter what conductivity type of the diffusion isolation regions 6 is, the p-type impurity is used for reduce the dangling bonds. FIGS. 14 and 15 are schematic views respectively illustrating the structures obtained after steps S03 and S04 of an embodiment of the method 1 (see the structure shown in FIG. 13).

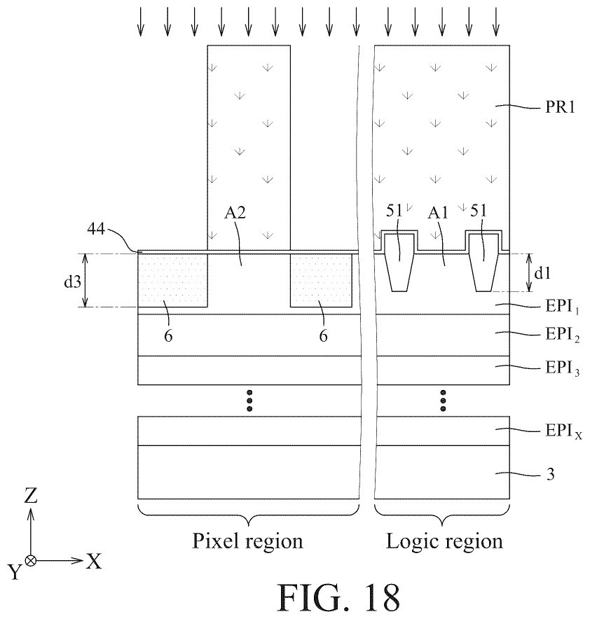

In some embodiments, the semiconductor structure shown in FIG. 19 may not formed with the second trench isolations 52 (see FIG. 9). FIGS. 16 and 17 respectively illustrate two possible intermediate states in step S02 for forming the semiconductor structure shown in FIG. 19 in accordance with some embodiments. Step S02 may be performed in a manner similar to that as described above with reference to FIGS. 3 to 5, but the second depth (d2) is zero, and formation of the first dielectric layer 53 (see FIG. 4) is omitted. In such case, the pixel region of the sub-layer EPI₁ is not subjected to an etching process to form the second trench isolations (see FIG. 9). As shown in FIG. 17, after formation of the first trench isolations 51, a dielectric material (e.g., the second trench isolations 52) is absent in the pixel region. Therefore, a damage of the pixel region of the sub-layer EPI₁ caused by a plasma used in the etching process is prevented, thereby improving a pixel performance (e.g., dark current) of the pixel unit 8. FIGS. 18 and 19 are schematic views illustrating the structures obtained after steps S03 and S04 of an embodiment of the method 1 (see the structure shown in FIG. 17). Since the second trench isolations 52 are absent, after formation of the diffusion isolation regions 6, a dielectric material is absent in each of the two diffusion isolation regions 6.

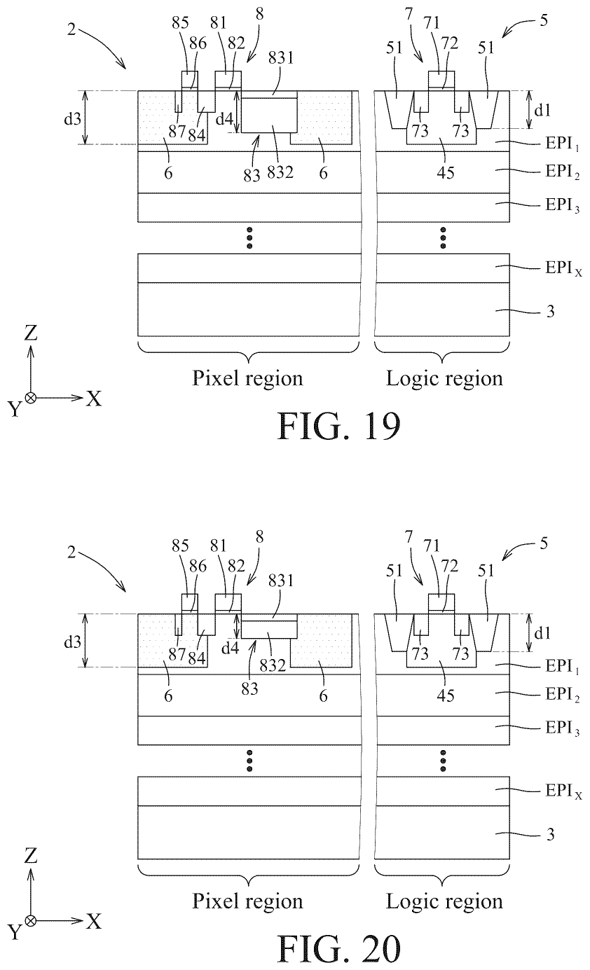

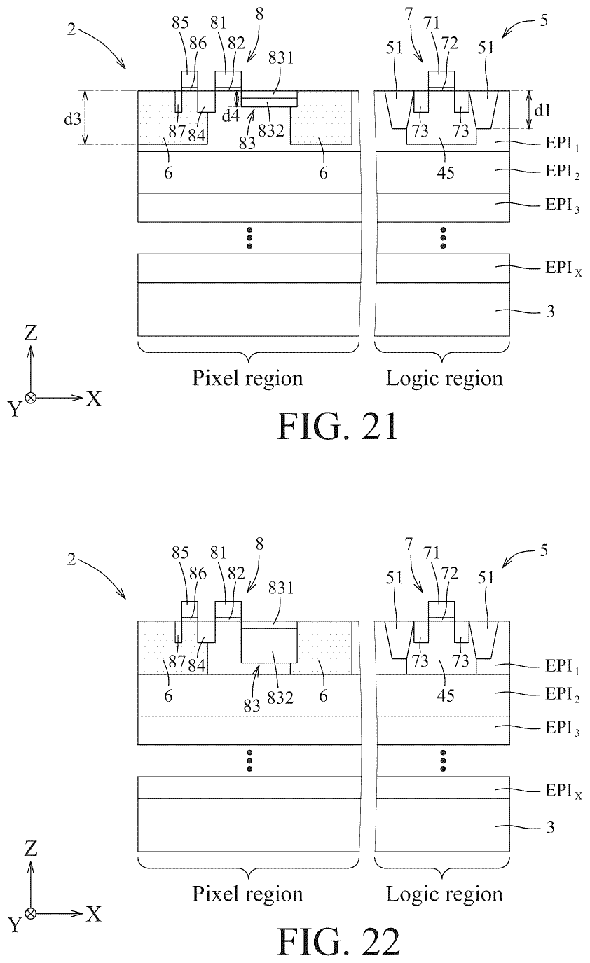

In some embodiments, the dopant concentration of the sub-layer EPI₁ may be adjusted according to practical applications. FIGS. 20 and 21 are schematic views similar to that shown in FIG. 19, but the dopant concentration of the sub-layer EPI₁ shown in FIGS. 20 and 21 is higher compared with the thickness of the sub-layer EPI₁ shown in FIG. 19. The dopant concentration of the sub-layer EPI₁ shown in FIG. 21 is greater than the dopant concentration of the sub-layer EPI₁ shown in FIG. 20, and the dopant concentration of the sub-layer EPI₁ shown in FIG. 20 is greater than the dopant concentration of the sub-layer EPI₁ shown in FIG. 19. The dopant concentration of the sub-layer EPI₁ shown in FIGS. 19 to 21 is also in a range of about 1E13 atoms/cm³ to about 1E15 atoms/cm³. As the dopant concentration of the sub-layer EPI₁ increases, when the process parameters for forming the diffusion isolation regions 6 and the photosensitive region 83 are not changed, the depth (d3) of the diffusion isolation regions 6 is substantially not changed, and the depth (d4) of the photosensitive region 83 is reduced. To be specific, a depth of the upper doped zone 831 is substantially not changed, and a depth of the lower doped zone 832 is reduced. Furthermore, in comparison with the pixel unit 8 in the semiconductor structure shown in each of FIGS. 19 and 20, the pixel unit 8 in the semiconductor structure 2 shown in FIG. 21 has an improved pixel performance (e.g., a reduced dark current) due to improved electrical isolation provided by the sub-layer EPI₁ with an increased dopant concentration.

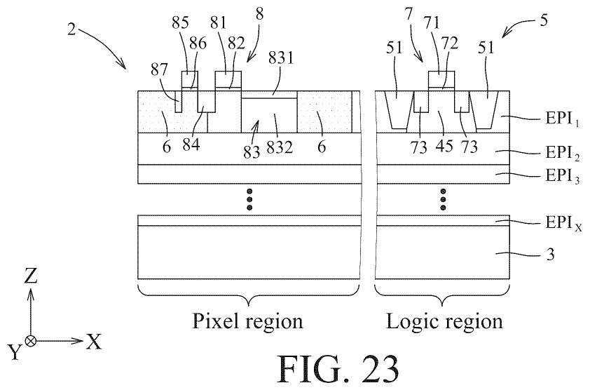

In some embodiments, the sub-layer EPI₁ may have reduced thickness. FIGS. 22 and 23 are schematic views similar to that shown in FIG. 19, but the thickness of the sub-layer EPI₁ shown in FIGS. 22 and 23 are greater compared with the thickness of the sub-layer EPI₁ shown in FIG. 19. The thickness of the sub-layer EPI₁ shown in FIG. 23 is less than the thickness of the sub-layer EPI₁ shown in FIG. 22, and the thickness of the sub-layer EPI₁ shown in FIG. 22 is less than the thickness of the sub-layer EPI₁ shown in FIG. 19. As the thickness of the sub-layer EPI₁ decreases, when the process parameters for forming the diffusion isolation regions 6 and the photosensitive region 83 are not changed, the diffusion isolation regions 6 may be in contact with the sub-layer EPI₂, as shown in FIG. 22. Further, as shown in FIG. 23, the diffusion isolation regions 6 and the photosensitive region 83 are in contact with the sub-layer EPI₂. In comparison with the pixel unit 8 in the semiconductor structure 2 shown in each of FIGS. 19 and 22, the pixel unit 8 in the semiconductor structure 2 shown in FIG. 23 has an improved pixel performance (e.g., a reduced dark current) because the sub-layer EPI₂ (having a dopant concentration greater than that of the diffusion isolation regions 6) can provide an improved electrical isolation.

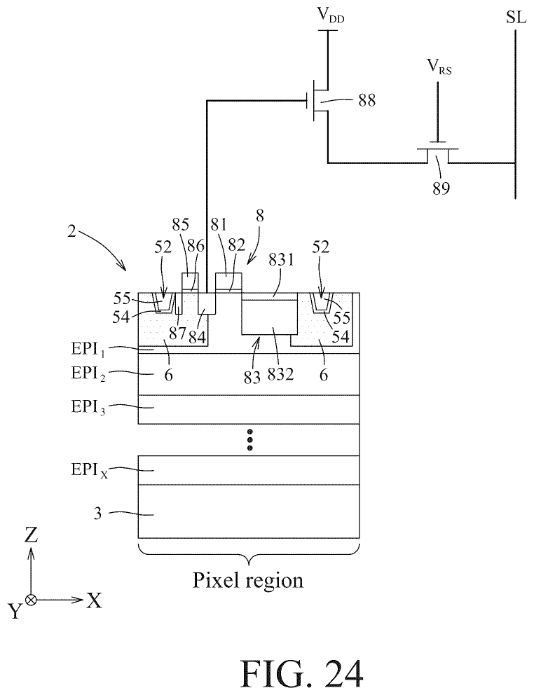

In some embodiments, the pixel unit 8 further includes a source follower transistor 88 coupled to the floating diffusion region 84 and a row selector transistor 89 coupled to the source follower transistor 88. FIG. 24 is a schematic view similar to that shown in FIG. 9, but further illustrating the source follower transistor 88 and the row selector transistor 89 in accordance with some embodiments. The logic region is not shown in FIG. 24 for the sake of brevity. In some embodiments, the source follower transistor 88 may be an amplifier transistor for amplifying the signal (e.g., stored charges) of the floating diffusion region 84 for readout operation. In some embodiments, in the source follower transistor 88, a source is coupled to a voltage (V_{DD}) and a gate electrode is coupled to the floating diffusion region 84, and a drain is coupled to the row selector transistor 89. In some embodiments, in the row selector transistor 89, a source is coupled to the drain of the source follower transistor 88, a gate electrode is coupled to a voltage (V_{RS}), and a drain is coupled to a signal line (SL) to selectively output the amplified signal.

In some embodiments, the logic and pixel regions of the semiconductor structure 2 has a layout as shown in FIG. 25 in accordance with some embodiments. The semiconductor structure 2 may include a plurality of the pixel units 8 (one of which is exemplarily shown in FIG. 9) formed in the pixel region and a plurality of the transistors 7 (one of which is exemplarily shown in FIG. 9) formed in the logic region. The pixel units 8 are arranged in an array in the X direction and a Y direction transverse to both the X and Z directions. In some embodiments, the X, Y and Z directions are perpendicular to each other. The layout of the semiconductor structure 2 may vary according to practical applications. Other possible layout suitable for the semiconductor structure 2 are within the contemplated scope of the present disclosure.

Referring to FIG. 26, which is the fragmentary enlarged view of area B of FIG. 25, the semiconductor structure 2 may include a plurality of the diffusion isolation regions 6. In some embodiments, any two of the diffusion isolation regions 6 are intersected with each other, such that the photosensitive region 83 of each of the pixel unit 8 is surrounded by four adjacent ones of the diffusion isolation regions 6.

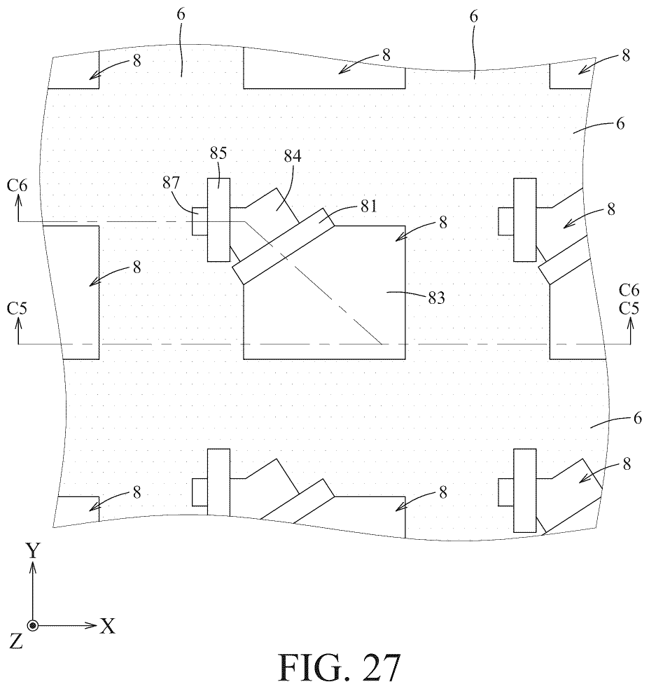

FIG. 27 is a schematic top view similar to that shown in FIG. 26, but the second trench isolations 52 are absent. In some embodiments, the pixel region shown in FIG. 18 is taken along line C5-C5 of FIG. 27, but illustrates the intermediate structure obtained after step S03, and the pixel region shown in FIG. 19 is taken along line C6-C6 of FIG. 27, but illustrates the intermediate structure obtained after step S04.

In summary, the photosensitive regions 83 of the pixel units 8 can be electrically isolated mainly or merely by the diffusion isolation regions 6. As the depth (d2) of the second trench isolations 52 decreases, the damage of the sub-layer EPI1 caused by plasma is reduced, thereby improving the pixel performance of the pixel unit 8. In the case that the depth (d2) is zero, the pixel unit 8 will demonstrate the best pixel performance, which may be further optimized by adjusting the dopant concentration or the thickness of the sub-layer EPI₁. Even in the case that the depth (d2) is greater than zero, the methods for repairing the defects (e.g., dangling bonds) on the inner surfaces of the second trenches 502 are also provided in the present disclosure.

In accordance with some embodiments of the present disclosure, a method for manufacturing a semiconductor structure includes: forming an epitaxial layer having a pixel region and a logic region displaced from each other; forming a dielectric structure in the epitaxial layer such that the dielectric structure has a first depth in the logic region and a second depth in the pixel region, the second depth being smaller than the first depth; forming two diffusion isolation regions in the pixel region such that the two diffusion isolation regions each has a third depth that is greater than each of the first depth and the second depth, the pixel region having a pixel active area between the two diffusion isolation regions; forming a transfer gate on the pixel active area; forming a photosensitive region in the pixel active area for converting an incident light into charges; and forming a floating diffusion region in the pixel active area such that the photosensitive region and the floating diffusion region are respectively located at two opposite sides of the transfer gate.

In accordance with some embodiments of the present disclosure, the second depth is zero.

In accordance with some embodiments of the present disclosure, the dielectric structure includes two first trench isolations each having the first depth, and the logic region has a logic active area between the two first trench isolations.

In accordance with some embodiments of the present disclosure, the method further includes: forming a logic gate on the logic active area; and forming two source/drain regions in the logic active area such that the two sources/drain regions are respectively located at two opposite sides of the logic gate.

In accordance with some embodiments of the present disclosure, the epitaxial layer and the two diffusion isolation regions each has a first conductivity type, and the two diffusion isolation regions each has a dopant concentration that is greater than a dopant concentration of the epitaxial layer.

In accordance with some embodiments of the present disclosure, the photosensitive region has an upper doped zone and a lower doped zone which is in contact with and located beneath the upper doped zone, the upper doped zone has the first conductivity type and has a dopant concentration that is greater than the dopant concentration of the epitaxial layer, and the lower doped zone has a second conductivity type that is opposite to the first conductivity type.

In accordance with some embodiments of the present disclosure, the second depth is greater than zero, the dielectric structure includes two first trench isolations each having the first depth, and two second trench isolations each having the second depth, and after formation of the two diffusion isolation regions, the two second trench isolations are respectively located within the two diffusion isolation regions.

In accordance with some embodiments of the present disclosure, the second depth is not greater than a half of the first depth.

In accordance with some embodiments of the present disclosure, formation of the dielectric structure includes patterning the logic region of the epitaxial layer to form two first trenches each having the first depth, patterning the pixel region of the epitaxial layer to form two second trenches each having the second depth, performing a treatment on inner surfaces of the two second trenches using a p-type impurity, and filling the two first trenches and the two second trenches with a dielectric material such that the two first trench isolations are respectively formed in the two first trenches and the two second trench isolations are respectively formed in the two second trenches.

In accordance with some embodiments of the present disclosure, in the treatment, the p-type impurity is implanted into the epitaxial layer with a depth not greater than 1000 Å from the inner surfaces of the two second trenches, and the p-type impurity includes boron, aluminum, gallium, indium, or combinations thereof.

In accordance with some embodiments of the present disclosure, formation of the dielectric structure includes patterning the logic region of the epitaxial layer to form two first trenches each having the first depth, patterning the pixel region of the epitaxial layer to form two second trenches each having the second depth, forming two dielectric films respectively on inner surfaces of the two second trenches, the two dielectric films including a first dielectric material, and filling the two first trenches and the two second trenches with a second dielectric material which is different from the first dielectric material such that the two first trench isolations are respectively formed in the two first trenches and the two second trench isolations are respectively formed in the two second trenches.

In accordance with some embodiments of the present disclosure, the first dielectric material includes metal oxide including hafnium, aluminum, tantalum, or combinations thereof, and the second dielectric material includes silicon oxide, silicon nitride, silicon oxynitride, carbon-doped silicon oxide, or silicon oxycarbon nitride.

In accordance with some embodiments of the present disclosure, a method for manufacturing a semiconductor structure, includes: forming an epitaxial layer over a substrate, the epitaxial layer including a first sub-layer and a second sub-layer which is immediately beneath the first sub-layer, and which has a dopant concentration greater than a dopant concentration of the first sub-layer, the first sub-layer having a pixel region and a logic region displaced from each other; forming a dielectric structure in the first sub-layer such that the dielectric structure has a first depth in the logic region and a second depth in the pixel region, the second depth being smaller than the first depth; forming two diffusion isolation regions in the pixel region such that the two diffusion isolation regions each has a third depth that is greater than each of the first depth and the second depth, the pixel region having a pixel active area between the two diffusion isolation regions; forming a transfer gate on the pixel active area; forming a photosensitive region in the pixel active area for converting an incident light into charges; and forming a floating diffusion region in the pixel active area such that the photosensitive region and the floating diffusion region are respectively located at two opposite sides of the transfer gate.

In accordance with some embodiments of the present disclosure, the photosensitive region has a fourth depth that is not greater than the third depth.

In accordance with some embodiments of the present disclosure, the epitaxial layer has a p-type conductivity, the photosensitive region has a p-type doped zone and an n-type doped zone which is in contact with and located beneath the p-type doped zone, and the two diffusion isolation regions have the p-type conductivity and each has a dopant concentration that is greater than the dopant concentration of the first sub-layer and that is less than the dopant concentration of the second sub-layer.

In accordance with some embodiments of the present disclosure, each of the two diffusion isolation regions is spaced apart from the second sub-layer.

In accordance with some embodiments of the present disclosure, each of the two diffusion isolation regions is in contact with the second sub-layer, and the n-type doped zone is in contact with the second sub-layer.

In accordance with some embodiments of the present disclosure, a semiconductor structure, includes: an epitaxial layer having a pixel region and a logic region displaced from each other; a dielectric structure formed in the epitaxial layer, the dielectric structure having a first depth in the logic region and a second depth in the pixel region, the second depth being smaller than the first depth; two diffusion isolation regions formed in the pixel region, the two diffusion isolation regions each having a third depth that is greater than each of the first depth and the second depth; a transistor including a logic gate formed on a logic active area of the logic region, and two source/drain regions which are formed in the logic active area, and which are respectively located at two opposite sides of the logic gate; and a pixel unit including a transfer gate formed on a pixel active area of the pixel region, the pixel active area being disposed between the two diffusion isolation regions, and a photosensitive region and a floating diffusion region which are formed in the pixel active area, and which are respectively located at two opposite sides of the transfer gate.

In accordance with some embodiments of the present disclosure, the second depth is zero.

In accordance with some embodiments of the present disclosure, the second depth is greater than zero, the dielectric structure includes two first trench isolations each having the first depth, and two second trench isolations each having the second depth, the logic active area is disposed between the two first trench isolations, and the two second trench isolations are respectively located within the two diffusion isolation regions.

In accordance with some embodiments of the present disclosure, a method for manufacturing a semiconductor structure, includes: forming an epitaxial layer having a pixel region and a logic region displaced from each other; forming two trench isolations in the logic region, so that the logic region includes a logic active area which is disposed between the two trench isolations; forming two diffusion isolation regions in the pixel region, so that the pixel region includes a pixel active area which is disposed between the two diffusion isolation regions, a dielectric material being absent in each of the two diffusion isolation regions; forming a logic gate and a transfer gate respectively on the logic active area and the pixel active area; forming two source/drain regions in the logic active region such that the two sources/drain regions are respectively located at two opposite sides of the logic gate; forming a photosensitive region in the pixel active area for converting an incident light into charges, the photosensitive region having a depth that is not greater than a depth of each of the two diffusion isolation regions; and forming a floating diffusion region in the pixel active area such that the photosensitive region and the floating diffusion region are respectively located at two opposite sides of the transfer gate.

In accordance with some embodiments of the present disclosure, the depth of each of the two diffusion isolation regions is greater than a depth of each of the two dielectric isolations.

In accordance with some embodiments of the present disclosure, the floating diffusion region in the pixel active area extends into an adjacent one of the diffusion isolation regions.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming an epitaxial layer having a pixel region and a logic region displaced from each other;
forming a dielectric structure in the epitaxial layer such that the dielectric structure has a first depth in the logic region and a second depth in the pixel region, the second depth being smaller than the first depth;
forming two diffusion isolation regions in the pixel region such that the two diffusion isolation regions each has a third depth that is greater than each of the first depth and the second depth, the pixel region having a pixel active area between the two diffusion isolation regions;
forming a transfer gate on the pixel active area;
forming a photosensitive region in the pixel active area for converting an incident light into charges; and
forming a floating diffusion region in the pixel active area such that the photosensitive region and the floating diffusion region are respectively located at two opposite sides of the transfer gate.

2. The method as claimed in claim 1, wherein the second depth is zero.

3. The method as claimed in claim 2, wherein the dielectric structure includes two first trench isolations each having the first depth, the logic region having a logic active area between the two first trench isolations.

4. The method as claimed in claim 2, further comprising:
forming a logic gate on the logic active area; and
forming two source/drain regions in the logic active area such that the two sources/drain regions are respectively located at two opposite sides of the logic gate.

5. The method as claimed in claim 1, wherein
the epitaxial layer and the two diffusion isolation regions each has a first conductivity type, and
the two diffusion isolation regions each has a dopant concentration that is greater than a dopant concentration of the epitaxial layer.

6. The method as claimed in claim 5, wherein
the photosensitive region has an upper doped zone and a lower doped zone which is in contact with and located beneath the upper doped zone,
the upper doped zone has the first conductivity type and has a dopant concentration that is greater than the dopant concentration of the epitaxial layer, and
the lower doped zone has a second conductivity type that is opposite to the first conductivity type.

7. The method as claimed in claim 1, wherein
the second depth is greater than zero,
the dielectric structure includes two first trench isolations each having the first depth, and two second trench isolations each having the second depth, and
after formation of the two diffusion isolation regions, the two second trench isolations are respectively located within the two diffusion isolation regions.

8. The method as claimed in claim 7, wherein the second depth is not greater than a half of the first depth.

9. The method as claimed in claim 7, wherein formation of the dielectric structure includes
patterning the logic region of the epitaxial layer to form two first trenches each having the first depth,
patterning the pixel region of the epitaxial layer to form two second trenches each having the second depth,
performing a treatment on inner surfaces of the two second trenches using a p-type impurity, and
filling the two first trenches and the two second trenches with a dielectric material such that the two first trench isolations are respectively formed in the two first trenches and the two second trench isolations are respectively formed in the two second trenches.

10. The method as claimed in claim 9, wherein
in the treatment, the p-type impurity is implanted into the epitaxial layer with a depth not greater than 1000 Å from the inner surfaces of the two second trenches, and
the p-type impurity includes boron, aluminum, gallium, indium, or combinations thereof.

11. The method as claimed in claim 7, wherein formation of the dielectric structure includes
patterning the logic region of the epitaxial layer to form two first trenches each having the first depth,
patterning the pixel region of the epitaxial layer to form two second trenches each having the second depth,
forming two dielectric films respectively on inner surfaces of the two second trenches, the two dielectric films including a first dielectric material, and
filling the two first trenches and the two second trenches with a second dielectric material which is different from the first dielectric material such that the two first trench isolations are respectively formed in the two first trenches and the two second trench isolations are respectively formed in the two second trenches.

12. The method as claimed in claim 11, wherein
the first dielectric material includes metal oxide including hafnium, aluminum, tantalum, or combinations thereof, and
the second dielectric material includes silicon oxide, silicon nitride, silicon oxynitride, carbon-doped silicon oxide, or silicon oxycarbon nitride.

13. A method for manufacturing a semiconductor structure, comprising:
forming an epitaxial layer over a substrate, the epitaxial layer including a first sub-layer and a second sub-layer which is immediately beneath the first sub-layer, and which has a dopant concentration greater than a dopant concentration of the first sub-layer, the first sub-layer having a pixel region and a logic region displaced from each other;
forming a dielectric structure in the first sub-layer such that the dielectric structure has a first depth in the logic region and a second depth in the pixel region, the second depth being smaller than the first depth;
forming two diffusion isolation regions in the pixel region such that the two diffusion isolation regions each has a third depth that is greater than each of the first depth and the second depth, the pixel region having a pixel active area between the two diffusion isolation regions;
forming a transfer gate on the pixel active area;
forming a photosensitive region in the pixel active area for converting an incident light into charges; and
forming a floating diffusion region in the pixel active area such that the photosensitive region and the floating diffusion region are respectively located at two opposite sides of the transfer gate.

14. The method as claimed in claim 13, wherein the photosensitive region has a fourth depth that is not greater than the third depth.

15. The method as claimed in claim 13, wherein
the epitaxial layer has a p-type conductivity,
the photosensitive region has a p-type doped zone and an n-type doped zone which is in contact with and located beneath the p-type doped zone, and
the two diffusion isolation regions have the p-type conductivity and each has a dopant concentration that is greater than the dopant concentration of the first sub-layer and that is less than the dopant concentration of the second sub-layer.

16. The method as claimed in claim 15, wherein each of the two diffusion isolation regions is spaced apart from the second sub-layer.

17. The method as claimed in claim 15, wherein each of the two diffusion isolation regions is in contact with the second sub-layer, and the n-type doped zone is in contact with the second sub-layer.

18. A semiconductor structure, comprising:
an epitaxial layer having a pixel region and a logic region displaced from each other;
a dielectric structure formed in the epitaxial layer, the dielectric structure having a first depth in the logic region and a second depth in the pixel region, the second depth being smaller than the first depth;
two diffusion isolation regions formed in the pixel region, the two diffusion isolation regions each having a third depth that is greater than each of the first depth and the second depth;
a transistor including
a logic gate formed on a logic active area of the logic region, and
two source/drain regions which are formed in the logic active area, and which are respectively located at two opposite sides of the logic gate; and
a pixel unit including
a transfer gate formed on a pixel active area of the pixel region, the pixel active area being disposed between the two diffusion isolation regions, and
a photosensitive region and a floating diffusion region which are formed in the pixel active area, and which are respectively located at two opposite sides of the transfer gate.

19. The semiconductor structure as claimed in claim 18, wherein the second depth is zero.

20. The semiconductor structure as claimed in claim 18, wherein
the second depth is greater than zero,
the dielectric structure includes two first trench isolations each having the first depth, and two second trench isolations each having the second depth,
the logic active area is disposed between the two first trench isolations, and
the two second trench isolations are respectively located within the two diffusion isolation regions.
